(19) United States
(12) Patent Application Publication
(10) Pub. No.: US 2019/0033653 A1
(43) Pub. Date: Jan. 31, 2019

(54) METHOD FOR FORMING PRESSURE ELECTRODE ON DISPLAY MODULE

(71) Applicant: HiDeep Inc., Gyeonggi-do (KR)

(72) Inventor: Young Ho CHO, Gyeonggi-do (KR)

(21) Appl. No.: 16/072,390

(22) PCT Filed: Sep. 13, 2016
(86) PCT No.: PCT/KR2016/010359

§ 371 Date: Jul. 24, 2018

(30) Foreign Application Priority Data
Feb. 1, 2016 (KR) 1020160012293

(51) Int. Cl. G02F 1/1333; G06F 3/044; H05K 3/10; G06F 3/041; G02F 1/1343

(52) U.S. Cl. CPC G02F 1/133305; G06F 3/044; H05K 3/10; G06F 2203/04105; G02F 1/13439; G02F 2001/133331; G06F 3/0414

(57) ABSTRACT

A method for forming a pressure electrode for detecting a touch pressure, on a display module including a liquid crystal layer or an organic material layer arranged between an upper glass layer and a lower glass layer, may be provided. The method includes: a pressure electrode forming step of forming the pressure electrode on a bottom surface of the lower glass layer by using Gravure printing method; and a liquid crystal layer or organic material layer forming step of forming the liquid crystal layer or the organic material layer on a top surface of the lower glass layer.

### CROSS-REFERENCE TO RELATED APPLICATION

The present application is a U.S. national stage application under 35 U.S.C. § 371 of PCT Application No. PCT/KR2016/010359, filed Sep. 13, 2016, which claims priority to Korean Patent Application No. 10-2016-0012293, filed Feb. 1, 2016. The disclosures of the aforementioned priority applications are incorporated herein by reference in their entireties.

### BACKGROUND

### Field

The present disclosure relates to a method for forming a pressure electrode and more particularly to a method for forming a pressure electrode capable of detecting a touch pressure on a display module.

### Description of the Related Art

Various kinds of input devices are being used to operate a computing system. For example, the input device includes a button, key, joystick and touch screen. Since the touch screen is easy and simple to operate, the touch screen is increasingly being used to operate the computing system.

The touch screen may constitute a touch surface of a touch input device including a touch sensor panel which may be a transparent panel including a touch-sensitive surface. The touch sensor panel is attached to the front side of a display screen, and then the touch-sensitive surface may cover the visible side of the display screen. The touch screen allows a user to operate the computing system by simply touching the touch screen by a finger, etc. Generally, the computing system recognizes the touch and a position of the touch on the touch screen and analyzes the touch, and thus, performs operations in accordance with the analysis.

Here, there is a demand for a touch input device capable of detecting not only the touch position according to the touch on the touch screen but a pressure magnitude of the touch without degrading the performance of a display module.

### SUMMARY

One embodiment is a method for forming a pressure electrode for detecting a touch pressure, on a display module including a liquid crystal layer or an organic material layer arranged between an upper glass layer and a lower glass layer. The method includes: a pressure electrode forming step of forming the pressure electrode on a bottom surface of the lower glass layer by using Gravure printing method; and a liquid crystal layer or organic material layer forming step of forming the liquid crystal layer or the organic material layer on a top surface of the lower glass layer.

The pressure electrode forming step may include: forming a pressure electrode pattern by injecting a pressure electrode constituent material into a groove formed in a Gravure roll; transferring the pressure electrode pattern to a blanket of a rotating transfer roll by rotating the Gravure roll; and transferring the pressure electrode pattern transferred to the blanket of the transfer roll to the bottom surface of the lower glass layer by rotating the transfer roll.

The pressure electrode forming step may include: forming a pressure electrode pattern in a groove formed in a Cliche plate by injecting a pressure electrode constituent material into the groove; transferring the pressure electrode pattern to a blanket of a transfer roll by rotating the transfer roll on the Cliché plate; and transferring the pressure electrode pattern transferred to the blanket of the transfer roll to the bottom surface of the lower glass layer by rotating the transfer roll.

The pressure electrode forming step may include: processing a pressure electrode pattern from a pressure electrode constituent material layer coated on the entire outer surface of a blanket of a transfer roll by rotating the transfer roll on a Cliche plate including a protrusion; and transferring the pressure electrode pattern processed on the blanket of the transfer roll to the bottom surface of the lower glass layer by rotating the transfer roll.

Another embodiment is a method for forming a pressure electrode for detecting a touch pressure, on a display module including a liquid crystal layer or an organic material layer arranged between an upper glass layer and a lower glass layer. The method includes: a pressure electrode forming step of forming the pressure electrode on a bottom surface of the lower glass layer by using an inkjet printing method; and a liquid crystal layer or organic material layer forming step of forming the liquid crystal layer or the organic material layer on a top surface of the lower glass layer.

The pressure electrode forming step may include: discharging a droplet through a nozzle and attaching to a surface of the lower glass layer; and drying a solvent of the droplet attached to the lower glass layer.

Further another embodiment is a method for forming a pressure electrode for detecting a touch pressure, on a display module including a liquid crystal layer or an organic material layer arranged between an upper glass layer and a lower glass layer. The method includes: a pressure electrode forming step of forming the pressure electrode on a bottom surface of the lower glass layer by using a screen printing method; and a liquid crystal layer or organic material layer forming step of forming the liquid crystal layer or the organic material layer on a top surface of the lower glass layer.

The pressure electrode forming step may include: placing a paste which is a pressure electrode constituent material on a screen pulled with a predetermined tension and moving a squeegee while pressing the squeegee down; and pushing and transferring the paste to a surface of the lower glass layer through a mesh of the screen.

The mesh may be made of stainless metal.

Yet another embodiment is a method for forming a pressure electrode for detecting a touch pressure, on a display module including a liquid crystal layer or an organic material layer arranged between an upper glass layer and a lower glass layer. The method includes: a pressure electrode forming step of forming the pressure electrode on a bottom surface of the lower glass layer by using a flexographic printing method; and a liquid crystal layer or organic material layer forming step of forming the liquid crystal layer or the organic material layer on a top surface of the lower glass layer.

The pressure electrode forming step may include: applying ink which is supplied as a pressure electrode constituent material from a supplier on an Anilox roller having a uniform grating; transferring the ink spread on a surface of the Anilox roller in an embossed pattern to a soft printing substrate mounted on a printing cylinder; and printing the ink transferred to the soft printing substrate on a surface of the lower glass layer which moves by the rotation of a hard printing roll.

Still another embodiment is a method for forming a pressure electrode for detecting a touch pressure, on a display module including a liquid crystal layer or an organic material layer arranged between an upper glass layer and a lower glass layer. The method includes: a pressure electrode forming step of forming the pressure electrode on a bottom surface of the lower glass layer by using a transfer printing method; and a liquid crystal layer or organic material layer forming step of forming the liquid crystal layer or the organic material layer on a top surface of the lower glass layer.

The pressure electrode forming step may include: coating ink which is supplied as a pressure electrode constituent material from a supplier on a transparent endless belt; and transferring the ink coated on a surface of the transparent endless belt to a surface of the lower glass layer by using laser.

The pressure electrode forming step may include: coating ink which is supplied as a pressure electrode constituent material from a supplier on a transparent endless belt; and transferring the ink coated on a surface of the transparent endless belt to a surface of the lower glass layer by using a heat radiating device.

### BRIEF DESCRIPTION OF THE DRAWINGS

FIG. 1 is a schematic view of a configuration of a capacitance type touch sensor panel and the operation thereof in accordance with an embodiment of the present invention;

FIGS. 2a to 2e are conceptual views showing a relative position of the touch sensor panel with respect to various display modules in a touch input device according to the embodiment;

FIGS. 3a and 3b show a method for detecting a touch pressure by detecting a mutual capacitance change amount in the touch input device according to the embodiment, and a structure of the same;

FIGS. 4, 5a, and 5b show a method for detecting a touch pressure by detecting a self-capacitance change amount in the touch input device according to the embodiment, and a structure of the same;

FIGS. 6a and 6b are cross sectional views showing embodiments of a pressure electrode 450, 460, or 455 formed on various display modules 200 in the touch input device according to the embodiment;

FIGS. 7a to 7d are views showing a process of forming the pressure electrode on the bottom surface of the display module in the touch input device according to the embodiment;

FIG. 8 is a view for describing a method for forming the pressure electrode 450, 460, or 455 on a second glass layer 283 by using a roll-type printing method;

FIG. 9 is a view for describing a method for forming the pressure electrode 450, 460, or 455 on the second glass layer 283 by using a sheet-type printing method;

FIG. 10 is a view for describing a method for forming the pressure electrode 450, 460, or 455 on the second glass layer 283 by using a reverse offset printing method;

FIG. 11 is a view for describing a method for forming the pressure electrode 450, 460, or 455 on the second glass layer 283 by using an inkjet printing method;

FIG. 12 is a view for describing a method for forming the pressure electrode 450, 460, or 455 on the second glass layer 283 by using a screen printing method;

FIG. 13 is a view for describing a method for forming the pressure electrode 450, 460, or 455 on the second glass layer 283 by using a flexography printing method;

FIG. 14 is a view for describing a method for forming the pressure electrode 450, 460, or 455 on the second glass layer 283 by using a transfer printing method.

### DETAILED DESCRIPTION

Specific embodiments of the present invention will be described in detail with reference to the accompanying drawings. The specific embodiments shown in the accompanying drawings will be described in enough detail that those skilled in the art are able to embody the present invention. Other embodiments other than the specific embodiments are mutually different, but do not have to be mutually exclusive. Additionally, it should be understood that the following detailed description is not intended to be limited.

The detailed descriptions of the specific embodiments shown in the accompanying drawings are intended to be read in connection with the accompanying drawings, which are to be considered part of the entire written description. Any reference to direction or orientation is merely intended for convenience of description and is not intended in any way to limit the scope of the present invention.

Specifically, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation.

Terms such as “attached,” “affixed,” “connected,” “coupled,” “interconnected,” and similar refer to a relationship wherein structures are attached, connected or fixed to one another either directly or indirectly through intervening structures, as well as both movable or rigid attachments or relationships, unless expressly described otherwise.

A touch input device according to an embodiment of the present invention can be used in portable electronic products such as a smartphone, a smartwatch, a tablet PC, a laptop computer, personal digital assistants (PDA), an MP3 player, a camera, a camcorder, an electronic dictionary, etc., but also in home appliances such as a home PC, TV, DVD, a refrigerator, an air conditioner, a microwave oven, etc. Also, the pressure detectable touch input device including a display module in accordance with the embodiment can be used without limitation in all of the products that require a device for display and input, such as an industrial control device, a medical equipment, etc.

Hereinafter, the touch input device according to the embodiment of the present invention will be described with reference to the accompanying drawings. While the following description shows a capacitance type touch sensor panel 100 and a pressure detection module 400, the capacitance type touch sensor panel 100 and the pressure detection module 400 which are capable of detecting a touch position and/or a touch pressure in any manner can be also applied.

FIG. 1 is a schematic view of a configuration of the capacitance type touch sensor panel 100 and the operation thereof in accordance with an embodiment of the present invention. Referring to FIG. 1, the touch sensor panel 100 according to the embodiment may include a plurality of drive electrodes TX1 to TXn and a plurality of receiving electrodes RX1 to RXm, and may include a drive unit 120 which applies a drive signal to the plurality of drive electrodes TX1 to TXn for the purpose of the operation of the touch sensor panel 100, and a sensing unit 110 which detects the touch and the touch position by receiving a sensing signal including information on the capacitance change amount changing according to the touch on the touch surface of the touch sensor panel 100.

As shown in FIG. 1, the touch sensor panel 100 may include the plurality of drive electrodes TX1 to TXn and the plurality of receiving electrodes RX1 to RXm. While FIG. 1 shows that the plurality of drive electrodes TX1 to TXn and the plurality of receiving electrodes RX1 to RXm of the touch sensor panel 100 form an orthogonal array, the present invention is not limited to this. The plurality of drive electrodes TX1 to TXn and the plurality of receiving electrodes RX1 to RXm has an array of arbitrary dimension, for example, a diagonal array, a concentric array, a 3-dimensional random array, etc., and an array obtained by the application of them. Here, “n” and “m” are positive integers and may be the same as each other or may have different values. The magnitude of the value may be changed depending on the embodiment.

As shown in FIG. 1, the plurality of drive electrodes TX1 to TXn and the plurality of receiving electrodes RX1 to RXm may be arranged to cross each other. The drive electrode TX may include the plurality of drive electrodes TX1 to TXn extending in a first axial direction. The receiving electrode RX may include the plurality of receiving electrodes RX1 to RXm extending in a second axial direction crossing the first axial direction.

In the touch sensor panel 100 according to the embodiment of the present invention, the plurality of drive electrodes TX1 to TXn and the plurality of receiving electrodes RX1 to RXm may be formed in the same layer. For example, the plurality of drive electrodes TX1 to TXn and the plurality of receiving electrodes RX1 to RXm may be formed on the same side of an insulation layer (not shown). Also, the plurality of drive electrodes TX1 to TXn and the plurality of receiving electrodes RX1 to RXm may be formed in different layers. For example, the plurality of drive electrodes TX1 to TXn and the plurality of receiving electrodes RX1 to RXm may be formed on both sides of one insulation layer (not shown) respectively, or the plurality of drive electrodes TX1 to TXn may be formed on a side of a first insulation layer (not shown) and the plurality of receiving electrodes RX1 to RXm may be formed on a side of a second insulation layer (not shown) different from the first insulation layer.

The plurality of drive electrodes TX1 to TXn and the plurality of receiving electrodes RX1 to RXm may be made of a transparent conductive material (for example, indium tin oxide (ITO) or antimony tin oxide (ATO) which is made of tin oxide (SnO₂), and indium oxide (In₂O₃), etc.), or the like. However, this is only an example. The drive electrode TX and the receiving electrode RX may be also made of another transparent conductive material or an opaque conductive material. For instance, the drive electrode TX and the receiving electrode RX may include at least any one of silver ink, copper, and carbon nanotube (CNT). Also, the drive electrode TX and the receiving electrode RX may be made of metal mesh or nano silver.

The drive unit 120 according to the embodiment of the present invention may apply a drive signal to the drive electrodes TX1 to TXn. In the embodiment of the present invention, one drive signal may be sequentially applied at a time to the first drive electrode TX1 to the n-th drive electrode TXn. The drive signal may be applied again repeatedly. This is only an example. The drive signal may be applied to the plurality of drive electrodes at the same time in accordance with the embodiment.

Through the receiving electrodes RX1 to RXm, the sensing unit 110 receives the sensing signal including information on a capacitance (Cm) 101 generated between the receiving electrodes RX1 to RXm and the drive electrodes TX1 to TXn to which the drive signal has been applied, thereby detecting whether or not the touch has occurred and the touch position. For example, the sensing signal may be a signal coupled by the capacitance (Cm) 101 generated between the receiving electrode RX and the drive electrode TX to which the drive signal has been applied. As such, the process of sensing the drive signal applied from the first drive electrode TX1 to the n-th drive electrode TXn through the receiving electrodes RX1 to RXm can be referred to as a process of scanning the touch sensor panel 100.

For example, the sensing unit 110 may include a receiver (not shown) which is connected to each of the receiving electrodes RX1 to RXm through a switch. The switch becomes the on-state in a time interval during which the signal of the corresponding receiving electrode RX is sensed, thereby allowing the receiver to sense the sensing signal from the receiving electrode RX. The receiver may include an amplifier (not shown) and a feedback capacitor coupled between the negative (−) input terminal of the amplifier and the output terminal of the amplifier, i.e., coupled to a feedback path. Here, the positive (+) input terminal of the amplifier may be connected to the ground. Also, the receiver may further include a reset switch which is connected in parallel with the feedback capacitor. The reset switch may reset the conversion from current to voltage that is performed by the receiver. The negative input terminal of the amplifier is connected to the corresponding receiving electrode RX and receives and integrates a current signal including information on the capacitance (CM) 101, and then converts the integrated current signal into voltage. The sensing unit 110 may further include an analog to digital converter (ADC) (not shown) which converts the integrated data by the receiver into digital data. Later, the digital data may be input to a processor (not shown) and processed to obtain information on the touch on the touch sensor panel 100. The sensing unit 110 may include the ADC and processor as well as the receiver.

A controller 130 may perform a function of controlling the operations of the drive unit 120 and the sensing unit 110. For example, the controller 130 generates and transmits a drive control signal to the drive unit 120, so that the drive signal can be applied to a predetermined drive electrode TX1 at a predetermined time. Also, the controller 130 generates and transmits the drive control signal to the sensing unit 110, so that the sensing unit 110 may receive the sensing signal from the predetermined receiving electrode RX at a predetermined time and perform a predetermined function.

In FIG. 1, the drive unit 120 and the sensing unit 110 may constitute a touch detection device (not shown) capable of detecting whether or not the touch has occurred on the touch sensor panel 100 according to the embodiment and the touch position. The touch detection device according to the embodiment may further include the controller 130. The touch detection device according to the embodiment may be integrated and implemented on a touch sensing integrated circuit (IC) in a touch input device 1000 including the touch sensor panel 100. The drive electrode TX and the receiving electrode RX included in the touch sensor panel 100 may be connected to the drive unit 120 and the sensing unit 110 included in the touch sensing IC (not shown) through, for example, a conductive trace and/or a conductive pattern printed on a circuit board, or the like. The touch sensing IC may be placed on a circuit board on which the conductive pattern has been printed, for example, a first printed circuit board (hereafter, referred to as a first PCB). According to the embodiment, the touch sensing IC (not shown) may be mounted on a main board for operation of the touch input device 1000.

As described above, a capacitance (C) with a predetermined value is generated at each crossing of the drive electrode TX and the receiving electrode RX. When an object such as finger approaches close to the touch sensor panel 100, the value of the capacitance may be changed. In FIG. 1, the capacitance may represent a mutual capacitance (Cm). The sensing unit 110 senses such electrical characteristics, thereby being able to sense whether the touch has occurred on the touch sensor panel 100 or not and the touch position. For example, the sensing unit 110 is able to sense whether the touch has occurred on the surface of the touch sensor panel 100 comprised of a two-dimensional plane consisting of a first axis and a second axis and/or the touch position.

More specifically, when the touch occurs on the touch sensor panel 100, the drive electrode TX to which the drive signal has been applied is detected, so that the position of the second axial direction of the touch can be detected. Likewise, when the touch occurs on the touch sensor panel 100, a capacitance change is detected from the reception signal received through the receiving electrode RX, so that the position of the first axial direction of the touch can be detected.

The mutual capacitance type touch sensor panel as the touch sensor panel 100 has been described in detail in the foregoing. However, in the touch input device 1000 according to the embodiment of the present invention, the touch sensor panel 100 for detecting whether or not the touch has occurred and the touch position may be implemented by using not only the above-described method but also any touch sensing method like a self-capacitance type method, a surface capacitance type method, a projected capacitance type method, a resistance film method, a surface acoustic wave (SAW) method, an infrared method, an optical imaging method, a dispersive signal technology, and an acoustic pulse recognition method, etc.

In the touch input device 1000 according to the embodiment, the touch sensor panel 100 for detecting the touch position may be positioned outside or inside a display module 200.

The display module 200 of the touch input device 1000 according to the embodiment may be a display panel included in a liquid crystal display (LCD), a plasma display panel (PDP), an organic light emitting diode (OLED), etc. Accordingly, a user may perform the input operation by touching the touch surface while visually identifying an image displayed on the display panel. Here, the display module 200 may include a control circuit which receives an input from an application processor (AP) or a central processing unit (CPU) on a main board for the operation of the touch input device 1000 and displays the contents that the user wants on the display panel. The control circuit may be mounted on a second printed circuit board (hereafter, referred to as a second PCB). Here, the control circuit for the operation of the display panel 200 may include a display panel control IC, a graphic controller IC, and a circuit required to operate other display panels 200.

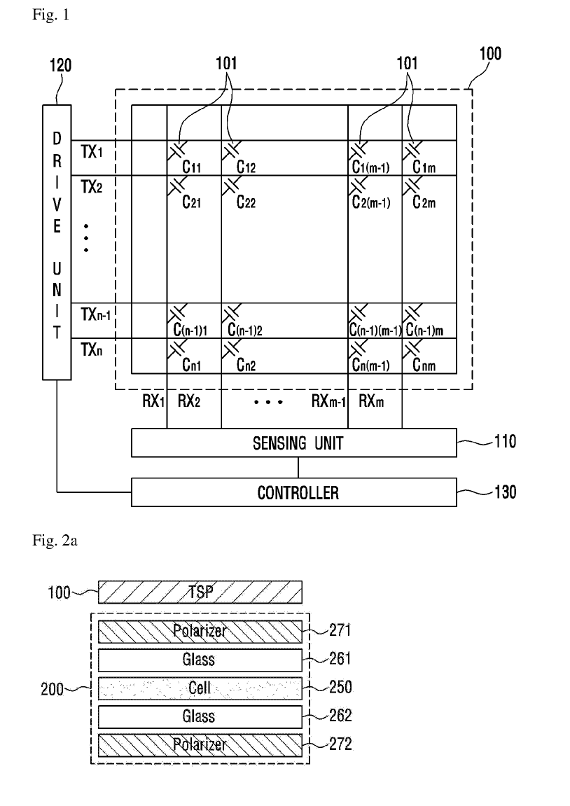

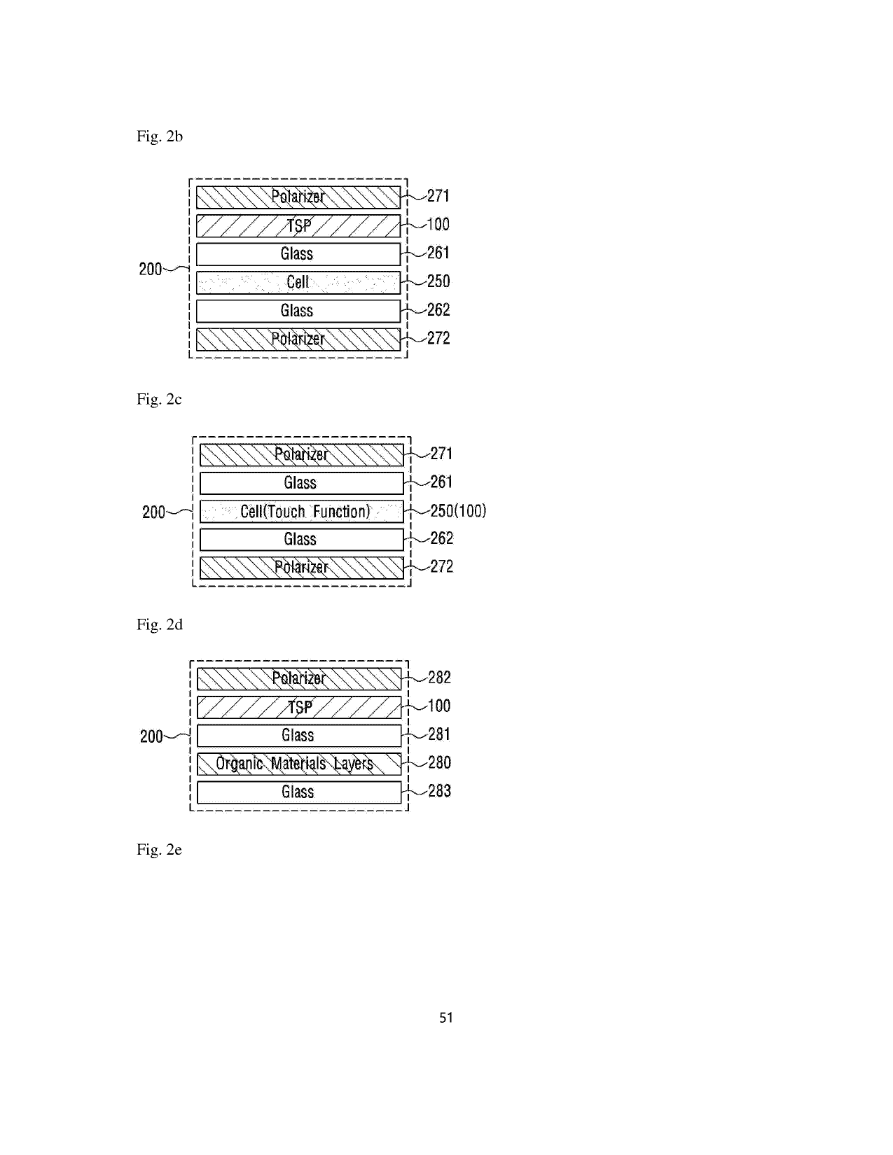

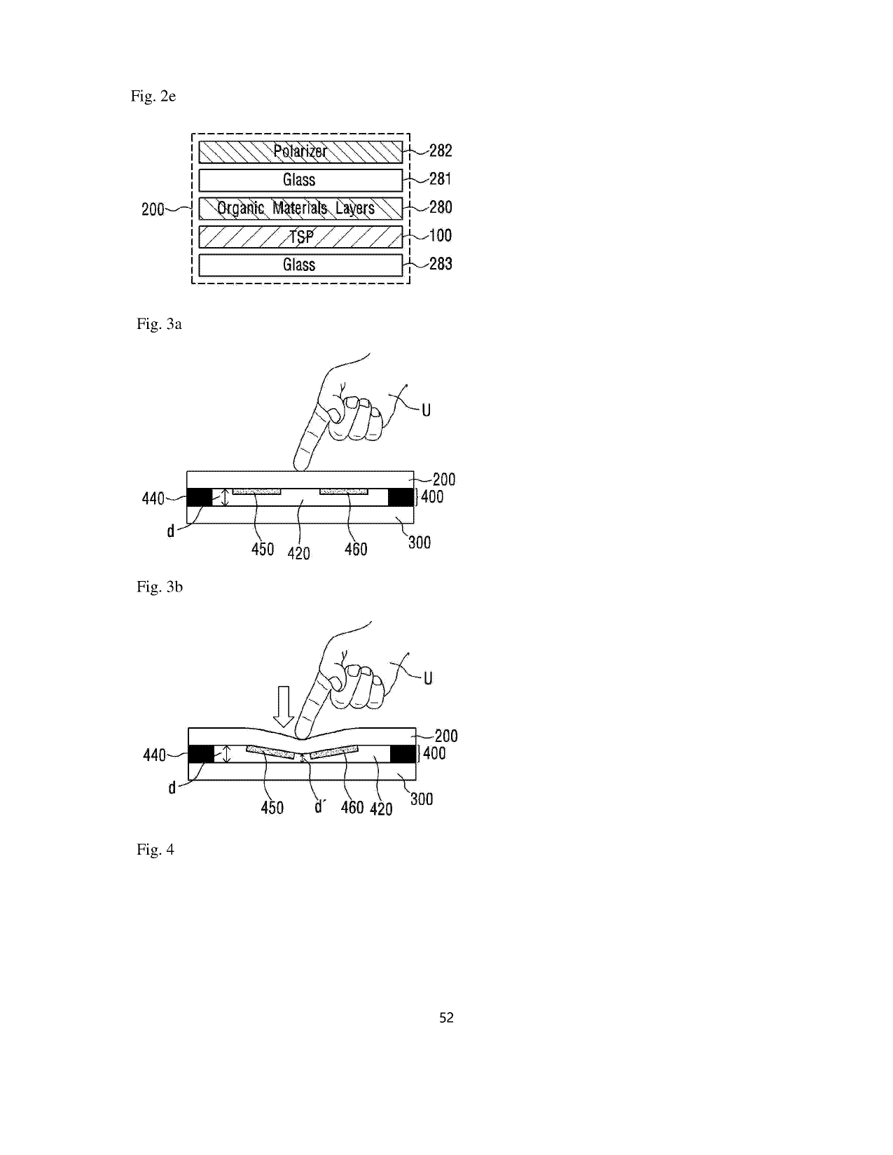

FIGS. 2a to 2e are conceptual views showing a relative position of the touch sensor panel with respect to the display module in a touch input device according to the embodiment.

FIGS. 2a to 2c are conceptual views showing a relative position of the touch sensor panel with respect to the display module in a touch input device according to the embodiment.

In this specification, while the reference numeral 200 designates the display module, the reference numeral 200 may designate the display panel as well as the display module in FIGS. 2A to 2E and the descriptions thereof. As shown in FIGS. 2A to 2C, the LCD panel may include a liquid crystal layer 250 including a liquid crystal cell, a first glass layer 261 and a second glass layer 262 which are disposed on both sides of the liquid crystal layer 250 and include electrodes, a first polarizer layer 271 formed on a side of the first glass layer 261 in a direction facing the liquid crystal layer 250, and a second polarizer layer 272 formed on a side of the second glass layer 262 in the direction facing the liquid crystal layer 250. Here, the first glass layer 261 may be a color filter glass, and the second glass layer 262 may be a TFT glass.

It is clear to those skilled in the art that the LCD panel may further include other configurations for the purpose of performing the displaying function and may be transformed.

FIG. 2a shows that the touch sensor panel 100 of the touch input device 1000 is disposed outside the display module 200. The touch surface of the touch input device 1000 may be the surface of the touch sensor panel 100. In FIG. 2a, the top surface of the touch sensor panel 100 is able to function as the touch surface. Also, according to the embodiment, the touch surface of the touch input device 1000 may be the outer surface of the display module 200. In FIG. 2a, the bottom surface of the second polarizer layer 272 of the display module 200 is able to function as the touch surface. Here, in order to protect the display module 200, the bottom surface of the display module 200 may be covered with a cover layer (not shown) such as glass.

FIGS. 2b and 2c show that the touch sensor panel 100 of the touch input device 1000 is disposed within the display panel 200. Here, in FIG. 2b, the touch sensor panel 100 for detecting the touch position is disposed between the first glass layer 261 and the first polarizer layer 271. Here, the touch surface of the touch input device 1000 is the outer surface of the display module 200. The top surface or bottom surface of the display module 200 in FIG. 2b may be the touch surface. FIG. 2c shows that the touch sensor panel 100 for detecting the touch position is included in the liquid crystal layer 250. Here, the touch surface of the touch input device 1000 is the outer surface of the display module 200. The top surface or bottom surface of the display module 200 in FIG. 2c may be the touch surface. In FIGS. 2b and 2c, the top surface or bottom surface of the display module 200, which can be the touch surface, may be covered with a cover layer (not shown) such as glass.

In the foregoing, it has been described that whether or not the touch has occurred on the touch sensor panel 100 according to the embodiment of the present invention and/or the touch position are detected. Also, it is possible to detect not only whether the touch has occurred or not and/or the touch position but also the magnitude of the touch pressure by using the touch sensor panel 100 according to the embodiment. Additionally, it is also possible to detect the magnitude of the touch pressure by further including a pressure detection module detecting the touch pressure separately from the touch sensor panel 100.

Next, a relative position of the touch sensor panel 100 with respect to the display module 200 using an OLED panel will be described with reference to FIGS. 2d and 2e. In FIG. 2d, the touch sensor panel 100 is located between a polarizer layer 282 and a first glass layer 281. In FIG. 2e, the touch sensor panel 100 is located between an organic layer 280 and a second glass layer 283. Here, the first glass layer 281 may be comprised of an encapsulation glass, and the second glass layer 283 may be comprised of a TFT glass. Since the touch sensing has been described above, only the other configurations thereof will be briefly described.

The OLED panel is a self-light emitting display panel which uses a principle in which current flows through a fluorescent or phosphorescent organic thin film and then electrons and electron holes are combined in the organic layer, so that light is generated. The organic matter constituting the light emitting layer determines the color of the light.

Specifically, the OLED uses a principle in which when electricity flows and an organic matter is applied on glass or plastic, the organic matter emits light. That is, the principle is that electron holes and electrons are injected into the anode and cathode of the organic matter respectively and are recombined in the light emitting layer, so that a high energy exciton is generated and the exciton releases the energy while falling down to a low energy state and then light with a particular wavelength is generated. Here, the color of the light is changed according to the organic matter of the light emitting layer.

The OLED includes a line-driven passive-matrix organic light-emitting diode (PM-OLED) and an individual driven active-matrix organic light-emitting diode (AM-OLED) in accordance with the operating characteristics of a pixel constituting a pixel matrix. None of them require a backlight. Therefore, the OLED enables a very thin display module to be implemented, has a constant contrast ratio according to an angle and obtains a good color reproductivity depending on a temperature. Also, it is very economical in that non-driven pixel does not consume power.

In terms of operation, the PM-OLED emits light only during a scanning time at a high current, and the AM-OLED maintains a light emitting state only during a frame time at a low current. Therefore, the AM-OLED has a resolution higher than that of the PM-OLED and is advantageous for driving a large area display panel and consumes low power. Also, a thin film transistor (TFT) is embedded in the AM-OLED, and thus, each component can be individually controlled, so that it is easy to implement a delicate screen.

As shown in FIGS. 2d and 2e, basically, the OLED (particularly, AM-OLED) panel includes the polarizer layer 282, the first glass layer 281, the organic layer 280, and the second glass layer 283. Here, the first glass layer 281 may be an encapsulation glass and the second glass layer 283 may be a TFT glass. However, they are not limited to this.

Also, the organic layer 280 may include a hole injection layer (HIL), a hole transport layer (HTL), an electron injection layer (EIL), an electron transport layer (ETL), and an light-emitting layer (EML).

Briefly describing each of the layers, HIL injects electron holes and uses a material such as CuPc, etc. HTL functions to move the injected electron holes and mainly uses a material having a good hole mobility. Arylamine, TPD, and the like may be used as the HTL. The EIL and ETL inject and transport electrons. The injected electrons and electron holes are combined in the EML and emit light. The EML represents the color of the emitted light and is composed of a host determining the lifespan of the organic matter and an impurity (dopant) determining the color sense and efficiency. This just describes the basic structure of the organic layer 280 include in the OLED panel. The present invention is not limited to the layer structure or material, etc., of the organic layer 280.

The organic layer 280 is inserted between the anode (not shown) and a cathode (not shown). When the TFT becomes an on-state, a driving current is applied to the anode and the electron holes are injected, and the electrons are injected to the cathode. Then, the electron holes and electrons move to the organic layer 280 and emit the light.

Up to now, the touch position detection by the touch sensor panel 100 according to the embodiment of the present invention has been described. Additionally, through use of the touch sensor panel 100 according to the embodiment of the present invention, it is possible to detect the magnitude of the touch pressure as well as whether the touch has occurred or not and/or where the touch has occurred. Also, the pressure detection module for detecting the touch pressure is further included separately from the touch sensor panel 100, so that it is possible to detect the magnitude of the touch pressure. Hereafter, touch pressure detection using the pressure detection module will be described in detail.

The touch input device 1000 according to the embodiment is able to detect the touch position through the above-described touch sensor panel 100 and to detect the touch pressure by disposing the pressure detection module 400 between the display module 200 and a substrate 300.

Hereinafter, the touch pressure detection which is performed by the pressure detection module 400 of the touch input device 1000 according to the embodiment and the structure for the touch pressure detection will be described.

FIGS. 3a and 3b show a method for detecting a touch pressure by detecting a mutual capacitance change amount, and a structure of the same. While the pressure detection module 400 shown in FIGS. 3a and 3b includes a spacer layer 420 composed of, for example, an air-gap, the spacer layer 420 may be made of a shock absorbing material or may be filled with a dielectric material in accordance with another embodiment.

The pressure detection module 400 may include a pressure electrode 450 and 460 disposed within the spacer layer 420. Here, the pressure electrode 450 and 460 may be formed under the display module 200 in various ways. This will be described below in more detail. Since the pressure electrode 450 and 460 is included in the rear side of the display panel, the pressure electrode 450 and 460 can be made of any one of a transparent material or an opaque material.

In order to maintain the spacer layer 420, an adhesive tape 440 with a predetermined thickness may be formed along the circumference of the upper portion of the substrate 300. The adhesive tape 440 may be formed on the entire circumference of the substrate 300 (e.g., four sides of a quadrangle) or may be formed on some of the circumference. For example, the adhesive tape 440 may be attached to the top surface of the substrate 300 or to the bottom surface of the display module 200. The adhesive tape 440 may be a conductive tape in order that the substrate 300 and the display module 200 have the same electric potential. Also, the adhesive tape 440 may be a double adhesive tape. In the embodiment of the present invention, the adhesive tape 440 may be made of an inelastic material. In the embodiment of the present invention, when a pressure is applied to the display module 200, the display module 200 may be bent. Therefore, the magnitude of the touch pressure can be detected even though the adhesive tape 440 is not transformed by the pressure. Further, in the embodiment, a means for maintaining the spacer layer 420 is not limited to the adhesive tape 440. In another embodiment, various means as well as the adhesive tape 440 can be used.

As shown in FIGS. 3a and 3b, the pressure electrode for detecting the pressure includes the first electrode 450 and the second electrode 460. Here, any one of the first electrode 450 and the second electrode 460 may be a drive electrode, and the other may be a receiving electrode. A drive signal is applied to the drive electrode, and a sensing signal may be obtained through the receiving electrode. When voltage is applied, the mutual capacitance may be generated between the first electrode 450 and the second electrode 460.

FIG. 3b is a cross sectional view of the pressure detection module 400 when a pressure is applied by an object U. The bottom surface of the display module 200 may have a ground potential in order to block the noise. When the pressure is applied to the surface of the touch sensor panel 100 by the object U, the touch sensor panel 100 and the display module 200 may be bent.

As a result, a distance “d” between the pressure electrode pattern 450 and 460 and a reference potential layer having the ground potential may be reduced to “d′”. In this case, due to the reduction of the distance “d”, fringing capacitance is absorbed in the bottom surface of the display module 200, so that the mutual capacitance between the first electrode 450 and the second electrode 460 may be reduced. Therefore, the magnitude of the touch pressure can be calculated by obtaining the reduction amount of the mutual capacitance from the sensing signal obtained through the receiving electrode.

In the touch input device 1000 according to the embodiment of the present invention, the display module 200 may be bent by the applied pressure of the touch. The display module 200 may be bent in such a manner as to show the biggest transformation at the touch position. When the display module 200 is bent according to the embodiment, a position showing the biggest transformation may not match the touch position. However, the display module 200 may be shown to be bent at least at the touch position. For example, when the touch position approaches close to the border, edge, etc., of the display module 200, the most bent position of the display module 200 may not match the touch position. However, the display module 200 may be shown to be bent at least at the touch position.

Here, the top surface of the substrate 300 may also have the ground potential in order to block the noise. Therefore, in order to prevent the substrate 300 and the pressure electrode 450 and 460 from being short-circuited, the pressure electrode 450 and 460 may be formed on an insulation layer.

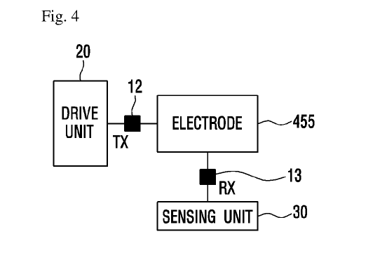

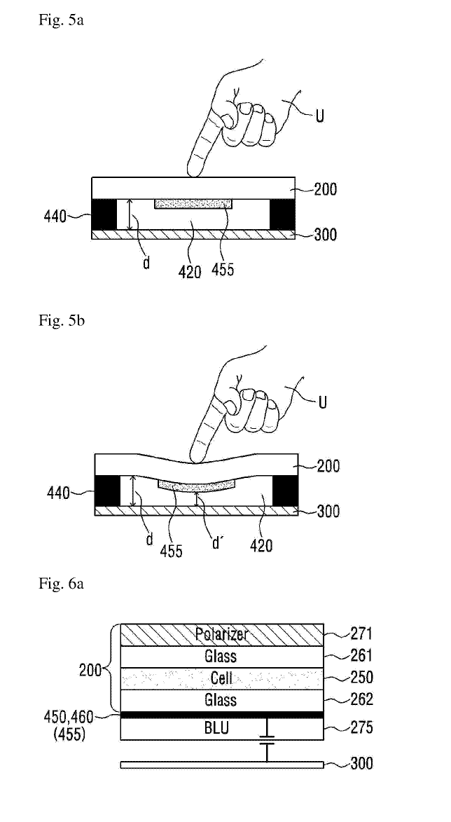

FIGS. 4, 5a, and 5b show a method for detecting the touch pressure by detecting a self-capacitance change amount, and a structure of the same.

The pressure detection module 400 for detecting the self-capacitance change amount uses a pressure electrode 455 formed on the bottom surface of the display module 200. When a drive signal is applied to the pressure electrode 455, the pressure electrode 455 receives a signal including information on the self-capacitance change amount and then detects the touch pressure.

The drive unit 20 applies a drive signal to the pressure electrode 455, and the sensing unit 30 measures a capacitance between the pressure electrode 455 and the reference potential layer 300 (e.g., substrate) having a reference potential through the pressure electrode 455, thereby detecting whether or not the touch pressure is applied and the magnitude of the touch pressure.

The drive unit 20 may include a clock generator (not shown) and a buffer, generate a drive signal in the form of a pulse, and apply to the pressure electrode 455. However, this is just an example. The drive unit may be implemented by means of various elements, and the shape of the drive signal may be variously changed.

The drive unit 20 and the sensing unit 30 may be implemented by an integrated circuit and may be formed on one chip. The drive unit 20 and the sensing unit 30 may constitute a pressure detector.

In order that the capacitance change amount is easily detected between the pressure electrode 455 and the reference potential layer 300, the pressure electrode 455 may be formed such that a larger facing surface between the pressure electrode 455 and the reference potential layer 300. For example, the pressure electrode 455 may be formed in a plate-like pattern.

With regard to the detection of the touch pressure in the self-capacitance type method, here, one pressure electrode 455 is taken as an example for description. However, the plurality of electrodes are included and a plurality of channels are constituted, so that it is possible to configure that the magnitude of multi pressure can be detected according to multi touch.

The capacitance between the pressure electrode 455 and the reference potential layer is changed by the change of the distance between the pressure electrode 455 and the reference potential layer 300. Then, the sensing unit 30 detects information on the capacitance change, and thus the touch pressure is detected.

FIG. 5a is a cross sectional view showing the display module 200 and the pressure detection module 400 in the touch input device 1000.

As shown in FIGS. 3a and 3b, the pressure electrode 455 may be disposed apart from the reference potential layer 300 at a predetermined distance “d”. Here, a material which is deformable by the pressure applied by the object U may be disposed between the pressure electrode 455 and the reference potential layer 300. For instance, the deformable material disposed between the pressure electrode 455 and the reference potential layer 300 may be air, dielectrics, an elastic body and/or a shock absorbing material.

When the object U presses the touch surface (herein, the top surface of the display module 200 or the top surface of the touch sensor panel 100), the pressure electrode 455 and the reference potential layer 300 become close to each other by the applied pressure, and the spaced distance “d” between them becomes smaller.

FIG. 5b shows that the pressure is applied by the object U and then the display module 200 and the pressure detection module 400 are bent downwardly. As the distance between the pressure electrode 455 and the reference potential layer 300 is reduced from “d” to “d′”, the capacitance is changed. Specifically, the self-capacitance generated between the pressure electrode 455 and the reference potential layer 300 is increased. The thus generated self-capacitance change amount is, as described above, measured by the sensing unit 30. Through this, it is possible to determine whether or not the touch pressure is applied and the magnitude of the touch pressure.

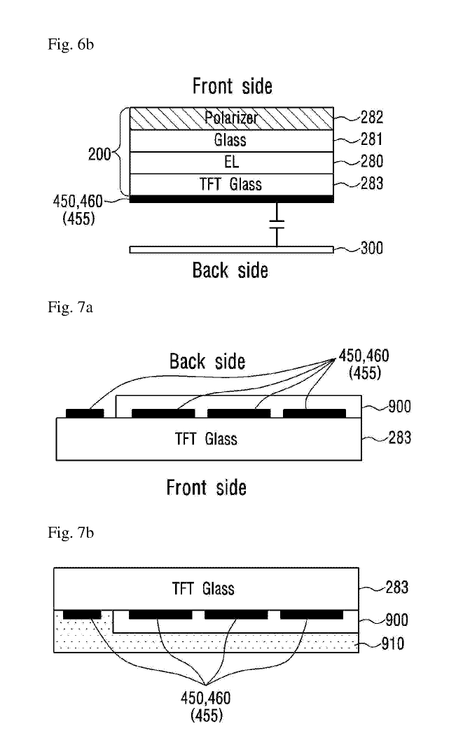

The pressure electrode 450, 460, or 455 for detecting the capacitance change amount may be formed on any one of the top surface and the bottom surface of the display module 200. FIGS. 6a and 6b are cross sectional views showing embodiments of the pressure electrode 450, 460, or 455 formed on various display modules 200.

First, FIG. 6a shows the pressure electrode 450, 460, or 455 formed within the display module 200 using the LCD panel. Here, when the touch pressure is detected based on the mutual capacitance change amount, the drive electrode 450 and the receiving electrode 460 are formed on one side of the display module 200 (specifically, the bottom surface of the display module 200, and more specifically, the bottom surface of the second glass layer 262 of the display module 200). Here, although it is shown in the drawing that the drive electrode 450 and the receiving electrode 460 are formed on the bottom surface of the second glass layer 262, the embodiment of the present invention is not limited thereto. For example, the drive electrode 450 and the receiving electrode 460 may be formed on the top surface of the second glass layer 262 or may be formed on one of the top surface and the bottom surface of the first glass layer 261.

Meanwhile, when the touch pressure is detected based on the self-capacitance change amount, the pressure electrode 455 is formed on one side within the display module 200 (specifically, the bottom surface of the display module 200, and more specifically, the bottom surface of the second glass layer 262). Here, although it is shown in the drawing that the pressure electrode 455 is formed on the bottom surface of the second glass layer 262, the embodiment of the present invention is not limited thereto. For example, the pressure electrode 455 may be formed on the top surface of the second glass layer 262 or may be formed on one of the top surface and the bottom surface of the first glass layer 261.

Although a relative position of the touch sensor panel 100 has been omitted in FIG. 6a, the embodiments of FIGS. 2a to 2c may be applied. Briefly describing, the touch sensor panel 100 may be, as shown in FIG. 2a, disposed outside the display module 200. Also, the touch sensor panel 100 may be, as shown in FIG. 2b or 2c, disposed within the display module 200 in such a manner as to be disposed between the first glass layer 261 and the first polarizer layer 271 or to be included within the liquid crystal layer 250.

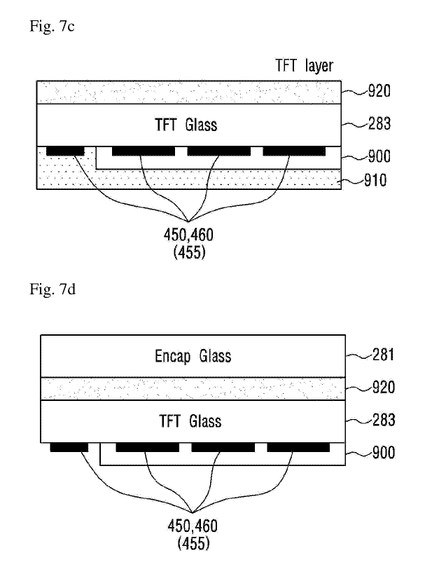

In the embodiment of FIG. 6a, the pressure electrode 450, 460, or 455 may be formed on one side of the display module 200. More specifically, the pressure electrode 450, 460, or 455 may be formed on the bottom surface of the second glass layer 262. Here, a pattern may be formed on the pressure electrode 450, 460, or 455 by using a display process. This will be described later with reference to FIGS. 7a to 7d.

Meanwhile, the LCD panel further includes a backlight unit 275. In FIG. 6a, the backlight unit 275 may be included under the second glass layer 262 on which the pressure electrode 450, 460, or 455 has been formed. However, this is just an embodiment. The backlight unit 275 may be configured in various ways.

Also, the reference potential layer 300 which is used to detect the touch pressure based on the capacitance change amount may be formed separately from the pressure electrode 450, 460, or 455 by a predetermined distance.

Next, FIG. 6b shows the pressure electrode 450, 460, or 455 formed on the back side of the display module 200 using the OLED panel (particularly, AM-OLED panel). Here, when the touch pressure is detected based on the mutual capacitance change amount, the drive electrode 450 and the receiving electrode 460 are formed on one side of the display module 200 (specifically, the bottom surface of the display module 200, and more specifically, the bottom surface of the second glass layer 283). Here, although it is shown in the drawing that the drive electrode 450 and the receiving electrode 460 are formed on the bottom surface of the second glass layer 283, the embodiment of the present invention is not limited thereto. For example, the drive electrode 450 and the receiving electrode 460 may be formed on the top surface of the second glass layer 283 or may be formed on one of the top surface and the bottom surface of the first glass layer 281.

Meanwhile, when the touch pressure is detected based on the self-capacitance change amount, the pressure electrode 455 is formed on one side of the display module 200 (specifically, the bottom surface of the display module 200, and more specifically, the bottom surface of the second glass layer 283). Here, although it is shown in the drawing that the pressure electrode 455 is formed on the bottom surface of the second glass layer 283, the embodiment of the present invention is not limited thereto. For example, the pressure electrode 455 may be formed on the top surface of the second glass layer 283 or may be formed on one of the top surface and the bottom surface of the first glass layer 281.

Although a relative position of the touch sensor panel 100 has been omitted in FIG. 6b, the embodiments of FIGS. 2d to 2e may be applied. Briefly describing, the touch sensor panel 100 may be, as shown in FIGS. 2d and 2e, disposed within the display module 200 in such a manner as to be disposed between the first glass layer 281 and the first polarizer layer 282 or to be included between the organic layer 280 and the second glass layer 283.

In the embodiment of FIG. 6b, the pressure electrode 450, 460, or 455 may be formed on one side within the display module 200. More specifically, the pressure electrode 450, 460, or 455 may be formed on the bottom surface of the second glass layer 283. Here, a pattern may be formed on the pressure electrode 450, 460, or 455 by using the display process. This will be described later with reference to FIGS. 7a to 7d.

Meanwhile, since the LCD panel does not require the backlight unit, only the reference potential layer 300 may be formed separately from the pressure electrode 450, 460, or 455 by a predetermined distance.

Hereinafter, the display process of forming the pressure electrode 450, 460, or 455 on the back side of the second glass layer 283 shown in FIG. 6b will be described. The display process of forming the pressure electrode 450, 460 or 455 on the bottom surface of the second glass layer 262 shown in FIG. 6a will be replaced by the following description. Here, it should be noted that the method for forming the pressure electrode 450, 460 or 455 shown in FIGS. 7a to 7d and FIGS. 8 to 10 is not limited to the bottom surface of the second glass layer 262 shown in FIG. 6a or the bottom surface of the second glass layer 283 shown in FIG. 6b. The method for forming the pressure electrode 450, 460 or 455 shown in FIGS. 7a to 7d and FIGS. 8 to 10 can be applied not only to the top surface or the bottom surface of the first glass layer 261 shown in FIG. 6a but also to the top surface or the bottom surface of the first glass layer 281 shown in FIG. 6b as it is.

FIGS. 7a to 7d are views showing a process of forming the pressure electrode on one side of the display module 200 in the touch input device according to the embodiment.

First, as shown in FIG. 7a, the second glass layer 283 is inverted and the pressure electrode 450, 460, or 455 is formed on the back side of the second glass layer 283. There are a variety of methods for forming the pressure electrode 450, 460, or 455. Several of the methods will be described.

Firstly, the electrode is formed by photolithography. First, the second glass layer 283 is inverted. Here, a cleaning process of removing impurities covered on the surface of the second glass layer 283 by using de-ionized water may be performed in advance. Then, a metallic material which is available as the pressure electrode 450, 460, or 455 is deposited on the bottom surface of the second glass layer 283 by physical vapor deposition or chemical vapor deposition. The metallic material may be Al, Mo, AlNd, MoTi, ITO, etc. Next, through use of a process such as spin coating, slit die coating, screen printing, dry film resist (DFR) laminating, etc., a photoresist is coated on the bottom surface of the second glass layer 283. The bottom surface of the second glass layer 283 to which the photoresist has been applied is exposed to light by using ultraviolet (UV). Here, if a positive photoresist (positive PR) is used at this time, the portion exposed to light is washed out by a developer due to chemical decomposition after being exposed to light. If a negative PR is used, the portion exposed to light is chemically combined with the light and a portion which has not been exposed to light is washed out by a developer after being exposed to light. The pattern exposed to light is developed by using a developer, and the photoresist of the portion exposed to light is removed. Here, an aqueous solution mixed with alkali such as sodium sulfite, sodium carbonate, etc., may be used as the developer. Next, a circuit is formed by melting the pattern of the film of the pressure electrode 450, 460, or 455 by means of chloride mixed gas, hydrofluoric acid, acetic acid, etc. Then, a pattern is formed by an etching process, and the photoresist remaining on the surface of the second glass layer 283 is removed. Lastly, impurities on the surface of the second glass layer 283 are removed by using de-ionized water again. As a result, the pressure electrode 450, 460, or 455 is formed. Through this method, a clean line of the pattern can be obtained and a fine pattern can be formed.

Secondly, the electrode is formed by using an etching resist. The etching resist refers to a film applied with the intention of partially preventing the etching or the material of the film. Organic matter, inorganic matter, metal, etc., can be used as the etching resist. First, impurities on the surface of the second glass layer 283 are removed by using de-ionized water. Then, a metallic material which is available as the pressure electrode 450, 460, or 455 is deposited on the bottom surface of the second glass layer 283 by physical vapor deposition or chemical vapor deposition. The metallic material may be Al, Mo, AlNd, MoTi, ITO, etc. Then, the etching resist is coated on the second glass layer 283 by screen printing, gravure coating inkjet coating, etc. After the etching resist is coated, a drying process is performed and etching process is performed. That is, the pattern portion of the pressure electrode 450, 460, or 455 deposited on the bottom surface of the second glass layer 283 is melted by an etching solution such as chloride mixed gas, hydrofluoric acid, acetic acid, etc., so that a circuit is formed. Then, the etching resist remaining on the surface of the second glass layer 283 is removed. This method does not need an exposure system, so that the electrode can be formed at a relatively low cost.

Thirdly, the electrode is formed by etching paste. When a metallic material is deposited on the bottom surface of the second glass layer 283, the etching paste is coated on the second glass layer 283 by using screen printing, gravure coating inkjet coating, etc. Then, in order to heighten the etch rate of the etching paste, the second glass layer 283 is heated at a high temperature of 80 to 120 t for approximately 5 to 10 minutes. Then, a cleaning process is performed, and thus, the pressure electrode 450, 460, or 455 is formed on the bottom surface of the second glass layer 283. However, unlike this, after the heating process is performed, a process of completely drying the etching paste can be considered to be included. The third method has a simple process and a reduced material cost. Also, when the drying process is further included, a fine pattern can be formed.

Through the above-described method, when the pressure electrode 450, 460, or 455 is formed on the bottom surface of the second glass layer 283, an insulator 900 is formed. This functions to protect the pressure electrode 450, 460, or 455 formed on the bottom surface of the second glass layer 283. The insulator 900 may be formed by the above-described method. Briefly describing, the insulator is deposited on the pressure electrode 450, 460, or 455 by physical vapor deposition or chemical vapor deposition, and the photoresist is coated and dried. Then, the exposure process is performed on the photoresist, and then the photoresist is etched. Lastly, a photoresist strip process of removing the remaining photoresist is performed, so that the electrode pattern is completed. Here, SiNx, SiOx, etc., may be used as the material of the insulator.

In the next place, in order to protect the pattern of the pressure electrode 450, 460, and 455 during the process, a protective layer 910 is formed. The protective layer 910 may be formed by coating or attaching. Here, for the purpose of protecting a component such as TFT, etc., which has a low hardness, it is desirable that the protective layer 910 should be made of a material having a hardness high enough to protect each layer. FIG. 7b shows that after the protective layer 910 is formed, the second glass layer 283 is inverted into its original position.

FIG. 7c shows that the configuration of the display module 200 which is stacked on the top surface of the second glass layer 283 is formed. Since FIG. 7c assumes the display module 200 including the OLED panel, a TFT layer 920 is shown to be formed. The TFT layer 920 includes basic components included in the OLED panel (particularly, AM-OLED panel). That is, the TFT layer 920 may include a TFT electrode as well as the cathode, organic layer, and anode, which have been described above with regard to the OLED panel. Also, various elements (e.g., over coat (OC), passivation (PAS), inter-layer dielectric (ILD), gate insulator (GI), light shield (LS), or the like) for stacking the components may be formed. The various elements may be formed by a variety of OLED panel forming processes.

Unlike this, regarding the display module 200 using the LCD panel, various elements including the liquid crystal layer may take the place of the TFT layer 920 of FIG. 7c.

Finally, when the first glass layer 281 is, as shown in FIG. 7d, formed on the TFT layer 920 and the protective layer 910 formed in FIG. 7b is removed chemically or physically, the display module 200 having the pressure electrode 450, 460, or 455 formed on the back side thereof is manufactured.

In the foregoing, the process of manufacturing the display module 200 having the pressure electrode 450, 460, or 455 formed thereon has been described with reference to FIGS. 7a to 7d. However, the order of the process may be changed or any one step in the process may be omitted. In other words, although the steps of FIGS. 7a to 7d may be the most optimal process order, the scope of the present invention is not limited to the order.

Through the above-described method, when the pressure electrode 450, 460, or 455 is formed on the back side of the display module 200 using the LCD panel or OLED panel, the touch input device 1000 capable of detecting the touch pressure can be thinner. Additionally, it is possible to reduce the manufacturing cost of the touch input device.

The method for forming the pressure electrode 450, 460, or 455 on the second glass layer 283 includes Gravure printing method (or roller printing method).

The Gravure printing method includes a Gravure offset printing method and a Reverse offset printing method. The Gravure offset printing method includes a roll type printing method and a sheet type printing method. Hereafter, the roll type printing method and the sheet type printing method which are included in the Gravure offset printing method, and the Reverse offset printing method will be described in turn with reference to the drawings.

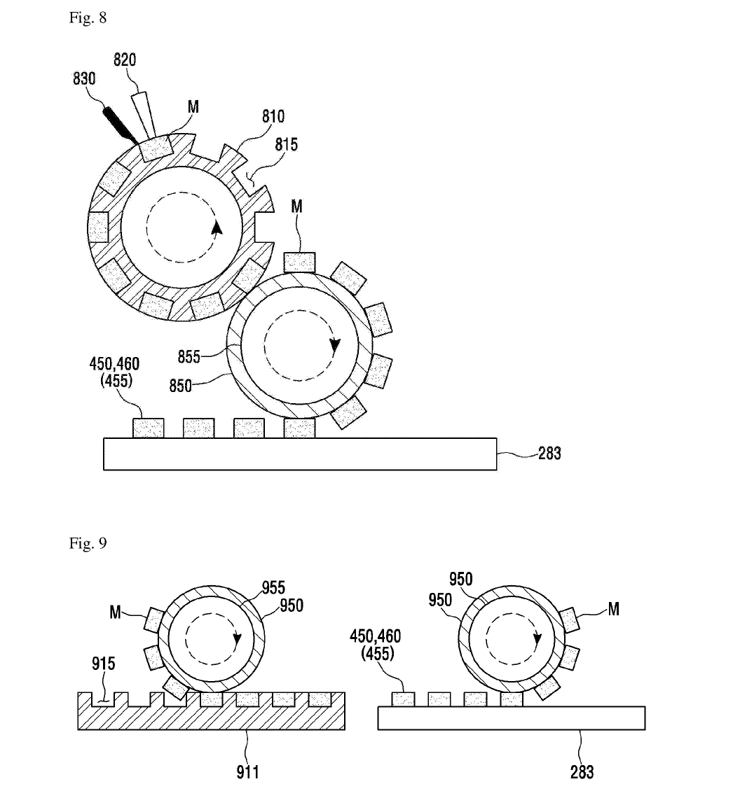

FIG. 8 is a view for describing the method for forming the pressure electrode 450, 460, or 455 on the second glass layer 283 by using a roll-type printing method.

Referring to FIG. 8, a pressure electrode constituent material is injected into a groove 815 formed in a Gravure roll 810 by using an injection unit 820. Here, the pressure electrode constituent material constituent material is filled in the groove 815 by using a blade 830. Here, the shape of the groove 815 corresponds to the shape of the pressure electrode 450, 460, or 455 to be printed on the bottom surface of the inverted second glass layer 283. The blade 830 functions to remove the excess amount of the pressure electrode constituent material overflowing the groove 815 and to push the pressure electrode constituent material into the groove 815. The injection unit 820 and the blade 830 are fixed and mounted around the Gravure roll 810. The Gravure roll 810 rotates counterclockwise.

The pressure electrode pattern M filled in the groove 815 of the Gravure roll 810 is transferred to a blanket 855 of a transfer roll 850 by rotating the Gravure roll 810. The rotation direction of the transfer roll 850 is opposite to the rotation direction of the Gravure roll 810. The blanket 855 may be made of a resin having a predetermined viscosity, particularly, silicon-based resin.

The transfer roll 850 is rotated and the pressure electrode pattern M transferred to the blanket 855 of the transfer roll 850 is transferred to the second glass layer 283. As a result, the pressure electrode 450, 460, or 455 may be formed on the bottom surface of the inverted second glass layer 283.

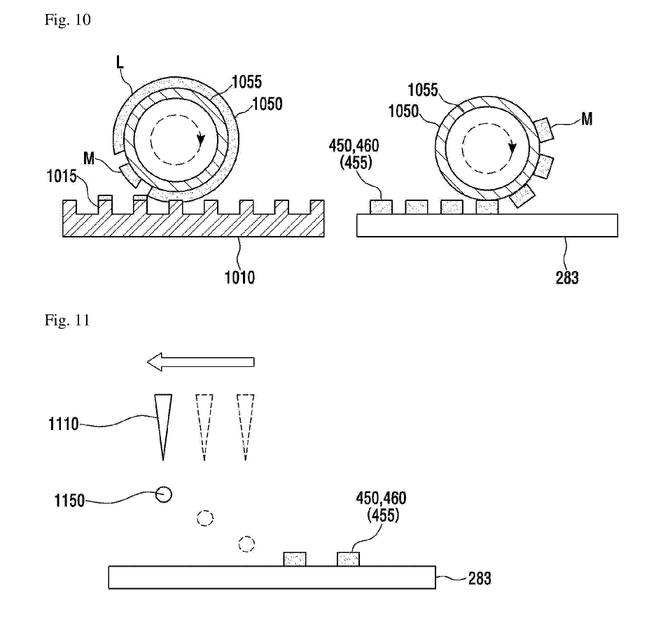

The roll type printing method shown in FIG. 8 has a better productivity than those of the methods shown in FIG. 9 or 10, and thus, is advantageous for forming the pressure electrode having a simple shape such as a stripe-shaped pressure electrode or a mesh-shaped pressure electrode.

FIG. 9 is a view for describing a method for forming the pressure electrode 450, 460, or 455 on the second glass layer 283 by using a sheet-type printing method.

Referring to FIG. 9, the pressure electrode constituent material is injected into a groove 915 of a Cliche plate 911, and the pressure electrode pattern M is formed in the groove 915.

A transfer roll 950 including a blanket 955 is rotated on the Cliche plate 911, and the pressure electrode pattern M is transferred to the blanket 955. Here, the transfer roll 950 is only rotated in a fixed state and the Cliche plate 911 can move under the transfer roll 950. Alternatively, the Cliche plate 911 is fixed and the transfer roll 950 can move with the rotation on the Cliche plate 911. The shape of the groove 915 corresponds to the shape of the pressure electrode 450, 460, or 455 to be printed on the bottom surface of the inverted second glass layer 283. The blanket 955 may be made of a resin having a predetermined viscosity, particularly, silicon-based resin.

When the pressure electrode pattern M is transferred to the blanket 955 of the transfer roll 950, the transfer roll 950 is rotated on the second glass layer 283 and the pressure electrode pattern M is transferred to the bottom surface of the second glass layer 283. As a result, the pressure electrode 450, 460, or 455 can be formed on the bottom surface of the inverted second glass layer 283. Here, the transfer roll 950 is only rotated in a fixed state and the second glass layer 283 can move under the transfer roll 950. Alternatively, the second glass layer 283 is fixed and the transfer roll 950 can move with the rotation on the second glass layer 283.

The sheet-type printing method shown in FIG. 9 has a higher printing precision than those of the methods shown in FIGS. 8 and 10 and spends a smaller amount of the pressure electrode constituent material (e.g., ink) than those of the methods shown in FIGS. 8 and 10.

FIG. 10 is a view for describing a method for forming the pressure electrode 450, 460, or 455 on the second glass layer 283 by using a reverse offset printing method.

Referring to FIG. 10, a transfer roll 1050 including a blanket 1055 is rotated on a Cliche plate 1010 including a protrusion 1015, and the pressure electrode pattern M is processed from a pressure electrode constituent material layer L coated on the entire outer surface of the blanket 1055. A portion of the pressure electrode constituent material layer L coated on the entire outer surface of the blanket 1055, which contacts the protrusion 1015, is transferred to the protrusion 1015 and the other portions, which do not contact the protrusion 1015, remain in the blanket 1055 as they are. Therefore, a predetermined pressure electrode pattern M of which the portions has been removed by the protrusion 1015 may be formed on the blanket 1055. Here, the transfer roll 1050 is only rotated in a fixed state and the Cliche plate 1010 can move under the transfer roll 1050. Alternatively, the Cliche plate 1010 is fixed and the transfer roll 1050 can move with the rotation on the Cliche plate 1010. The shape of the protrusion 1015 corresponds to the shape of the pressure electrode 450, 460, or 455 to be printed on the bottom surface of the inverted second glass layer 283. The blanket 1055 may be made of a resin having a predetermined viscosity, particularly, silicon-based resin.

When the pressure electrode pattern M is processed on the blanket 1055 of the transfer roll 1050, the transfer roll 1050 is rotated on the second glass layer 283, and the pressure electrode pattern M is transferred to the bottom surface of the second glass layer 283. As a result, the pressure electrode 450, 460, or 455 can be formed on the bottom surface of the inverted second glass layer 283. Here, the transfer roll 1050 is only rotated in a fixed state and the second glass layer 283 can move under the transfer roll 1050. Alternatively, the second glass layer 283 is fixed and the transfer roll 1050 can move with the rotation on the second glass layer 283.

The reverse offset printing method shown in FIG. 10 is advantageous for forming the large area pressure electrode as compared to the methods shown in FIGS. 8 to 9.

Through use of the Gravure printing method shown in FIGS. 8 to 10, the pressure electrode 450, 460, or 455 can be directly printed and formed on the second glass layer 283. Although the Gravure printing method has a somewhat lower resolution than the resolution of the above-described photolithography, etching resist method, and etching paste method, the pressure electrode formation process in the Gravure printing method is simpler than those of the above-described methods, and the Gravure printing method has a better productivity.

Also, the pressure electrode 450, 460, or 455 may be formed on the second glass layer 283 by the inkjet printing method.

The inkjet printing method means that a droplet (diameter less than 30 μm), i.e., the constituent material of the pressure electrode 450, 460, or 455 is discharged and then the pressure electrode 450, 460, or 455 is patterned on the second glass layer 283.

The inkjet printing method is suitable for implementing a complicated shape in a small volume in a non-contact manner. The inkjet printing method has a simple process, a reduced facility cost, and a reduced manufacturing cost. The inkjet printing method has a low environmental load and does not waste raw material because the material is accumulated at a desired pattern position and thus there is no material loss in principle. Also, like photolithography, the inkjet printing method does not require a process such as development and etching, etc., so that the characteristics of the substrate or material are not degraded by chemical effects. Also, since the inkjet printing method is performed in a non-contact manner, devices are not damaged by contact. A substrate having unevenness can be also patterned. When the printing is performed in an on-demand manner, the pattern shape can be directly edited and changed by a computer.

The inkjet printing method is divided into a continuous manner in which the droplet is continuously discharged and an on-demand manner in which the droplet is selectively discharged. The continuous manner is mainly used in low resolution marking because the continuous manner generally requires large devices and has low print quality, so that the continuous manner is not suitable for colorization. The on-demand manner is used for high resolution patterning.

The on-demand inkjet printing method includes a piezo method and a bubble jet method (thermal method). In the piezo method, the volume is changed by replacing an ink chamber with a piezoelectric element (which is deformed when a voltage is applied), and when a pressure is applied to the ink within the ink chamber, the ink is discharged through a nozzle. In the bubble jet method, bubbles are instantaneously generated by applying heat to the ink, and then the ink is discharged by the pressure. The bubble jet method is the most suitable for an office because it is easy to miniaturize and densify the device and the cost of the head is low. However, the head has a short durability life due to the heat application and the available ink is limited because the effect of the boiling point of solvent or heat damage to the ink material is inevitable. In comparison with this, in the piezo method, the densification and head cost are worse than those of the bubble jet method. However, the piezo method has an excellent durability life of the head and excellent flexibility of the ink because no heat is applied to the ink. Therefore, the piezo method is more suitable for commercial printing, industrial printing, and device manufacture as well as offices.

FIG. 11 is a view for describing a method for forming the pressure electrode 450, 460, or 455 on the second glass layer 283 by using the inkjet printing method.

Referring to FIG. 11, a fine droplet 1150 discharged through a nozzle 1110 flows in the air and is attached to the surface of the second glass layer 283, and the solvent is dried and a solid component is fixed, so that the pressure electrode 450, 460, or 455 is formed.

The size of the droplet 1150 is several to scores of p1 and the diameter of the droplet 1150 is about 10 μm. The droplet 1150 collides with and is attached to one side of the second glass layer 283 and then forms a predetermined pattern. The key factor for determining the resolution of the formed pattern is the size and wettability of the droplet 1150. The droplet 1150 dropped onto the second glass layer 283 spreads on the second glass layer 283 in a two dimensional way and finally becomes the pressure electrode 450, 460, or 455 having a size larger than that of the droplet 1150. The spread of the droplet 1150 depends on the kinetic energy at the time of colliding with the second glass layer 283 and on the wettability of the solvent. In the case of very fine droplet 1150, the kinetic energy has a very small effect and the wettability has a dominant effect. When the droplet 1150 has a lower wettability and a greater wetting angle, the spread of the droplet 1150 is restricted, so that the fine pressure electrode 450, 460, or 455 can be printed. However, if the wetting angle is too large, the droplets 1150 bounce and gather, so that the pressure electrode 450, 460, or 455 may not be formed. Therefore, in order to obtain the high resolution pressure electrode 450, 460, or 455, it is necessary to control the solvent selection or the surface condition of the second glass layer 283 so as to obtain an appropriate wetting angle. It is desirable that the wetting angle should be approximately 30 to 70 degrees. The solvent of the droplet 1150 attached to the second glass layer 283 is evaporated and the pressure electrode 450, 460, or 455 is fixed. In this step, the drying rate is high because the size of the droplet 1150 is very small.

In addition, the method for forming the pressure electrode 450, 460, or 455 on the second glass layer 283 includes a screen printing method.

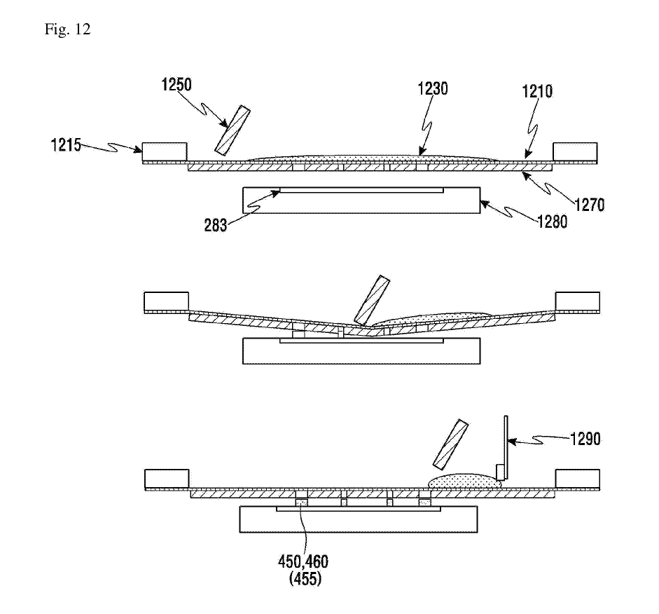

FIG. 12 is a view for describing a method for forming the pressure electrode 450, 460, or 455 on the second glass layer 283 by using the screen printing method.

As with the inkjet printing method, the screen printing method has a low material loss.

Referring to FIG. 12, a paste 1230, i.e., the pressure electrode constituent material, is placed on a screen 1210 pulled with a strong tension and a squeegee 1250 is moved while being pressed down. Then, the paste 1230 is pushed and transferred to the surface of the second glass layer 283 through a mesh of the screen 1210.

In FIG. 12, a reference numeral 1215 represents a screen frame. A reference numeral 1270 represents plastic emulsion. A reference numeral 1280 represents Nest which is mounted on the second glass layer 283. A reference numeral 1290 represents a flood blade.

The mesh of the screen 1210 may be made of stainless metal for the purpose of the fine pressure electrode 450, 460, or 455. Since the paste 1230 needs an appropriate viscosity, the paste 1230 may be obtained by dispersing a resin or solvent in a basic material such as metal powder or semiconductor, etc. According to the screen printing method, while an interval of several millimeters is maintained between the screen 1210 and the second glass layer 283, at the moment when the squeegee 1250 passes through the interval, the screen 1210 comes in contact with the second glass layer 283 and the paste 1230 is transferred. Though the screen printing method is a contact type printing method, there is little effect of the second glass layer 283 through the contact.

The screen printing method is performed through four basic processes such as rolling, discharging, plate separation, and leveling. The rolling means that the paste 1230 is rotated forward on the screen 1210 by the moving squeegee 1250. The rolling functions to stabilize the viscosity of the paste 1230 constantly and is an important process for obtaining a uniform thin film. The discharging means that the paste 1230 is pushed by the squeegee 1250, passes through between the screen 1210 and the mesh, and is pushed to the surface of the second glass layer 283. The discharge force depends on the moving speed of the squeegee 1250 and an angle formed by the squeegee 1250 with the screen 1210. The less the angle of the squeegee 1250 is and the less the moving speed is, the greater the discharge force is. The plate separation means that the screen 1210 is separated from the second glass layer 283 after the paste 1230 reaches the surface of the second glass layer 283. The plate separation is a very important process for determining the resolution and continuous printability. The paste 1230 which has passed through the screen 1210 and has reached the second glass layer 283 is spread with the fixing to the screen 1210 and the second glass layer 283. Therefore, it is preferable that the paste 1230 should be immediately separated from the screen 1210. For this purpose, the screen 1210 needs to be pulled with a high tension. The paste 1230 which has been discharged on the second glass layer 283 and has been plate-separated has fluidity. Therefore, the pressure electrode 450, 460, or 455 is likely to change, so that a mark or pin hole, etc., is generated in the mesh. As time goes by, the viscosity is increased due to the evaporation of the solvent, etc., and the fluidity is lost. Eventually, the pressure electrode 450, 460, or 455 is completed. This process is referred to as the leveling.

The printing condition of the pressure electrode 450, 460, or 455 by the screen printing method depends on the following four factors. \textcircled{1} clearance for stable plate separation \textcircled{2} the angle of the squeegee 1250 for discharging the paste 1230 \textcircled{3} the speed of the squeegee 1250, which affects the discharge of the paste 1230 and the plate separation speed, and \textcircled{4} the pressure of the squeegee 1250 which scrapes the paste 1230 on the screen 1210.

The thickness of the pressure electrode 450, 460, or 455 which is printed is determined by a discharge amount obtained through multiplication of the mesh thickness of the screen 1210 and an opening ratio. The accuracy of the pressure electrode 450, 460, or 455 depends on the fineness of the mesh. For the purpose of rapid plate separation, the screen 1210 needs to be pulled with a strong tension. However, when a fine patterning is performed by using the screen 1210 having a thin mesh, the tension may exceed the limit of a dimension stability that the screen 1210 having a thin mesh can endure. However, by using the screen 1210 to which a wire of about 16 μm is applied, the pressure electrode 450, 460, or 455 having a line width of less than 20 μm can be patterned.

In addition, the method for forming the pressure electrode 450, 460, or 455 on the second glass layer 283 includes a flexographic printing method.

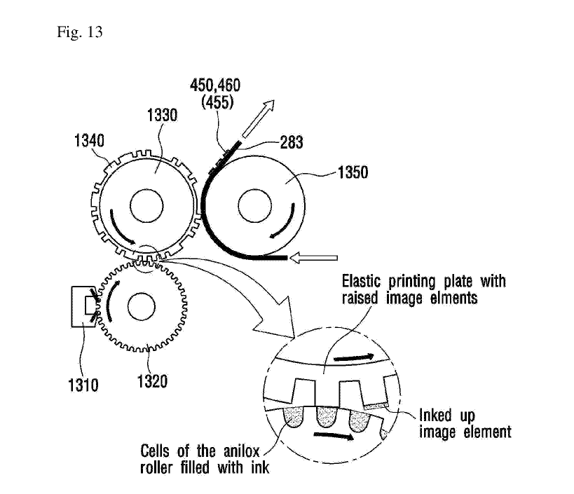

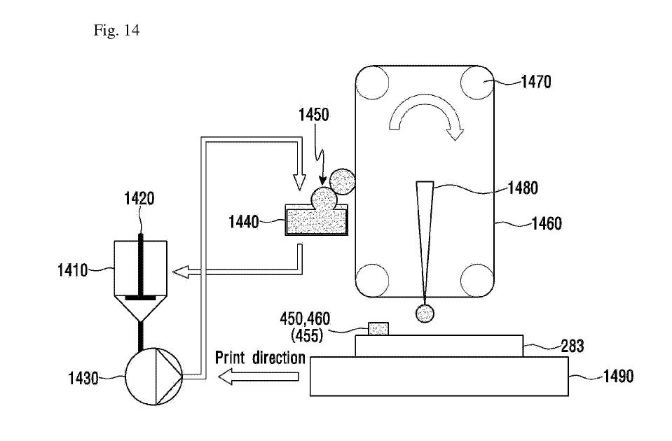

FIG. 13 is a view for describing a method for forming the pressure electrode 450, 460, or 455 on the second glass layer 283 by using the flexographic printing method.

Referring to FIG. 13, the ink, i.e., the pressure electrode constituent material which is supplied from a supplier 1310 is applied on an Anilox roller 1320 having a uniform grating, and is uniformly spread on the surface of the Anilox roller 1320 by using a doctor blade (not shown). Next, the ink spread on the surface of the Anilox roller 1320 is transferred in an embossed pattern to a soft printing substrate 1340 mounted on a printing cylinder 1330. Then, the ink transferred to the soft printing substrate 1340 is printed on the surface of the second glass layer 283 which moves by the rotation of a hard printing roll 1350. As a result, the pressure electrode 450, 460, or 455 is formed.

Regarding the flexographic printing method shown in FIG. 13, the thickness of the pressure electrode 450, 460, or 455 which is printed on the second glass layer 283 can be controlled by a pore size and density of the Anilox roller 1320, so that it is possible to form a uniform thin film. Also, the location or range in which the ink is applied can be precisely adjusted by changing the shape of the patterned pressure electrode 450, 460, or 455. Therefore, the flexographic printing method can be also applied to printing using a flexible substrate.

The flexographic printing method is used to apply an alignment film of the LCD. A polyimide alignment film having a uniform thickness is formed by the flexographic printing method and a rubbing method is used. Meanwhile, as the size of the second glass layer 283 is increased, the second glass layer 283 after the six generation (1500×1800) may have a form in which the printing roll 1350 moves.

Further, the method for forming the pressure electrode 450, 460, or 455 on the second glass layer 283 includes a transfer printing method. The transfer printing method includes a laser transfer printing method and a thermal transfer printing method.

FIG. 14 is a view for describing a method for forming the pressure electrode 450, 460, or 455 on the second glass layer 283 by using a transfer printing method.

Referring to FIG. 14, the ink, i.e., the pressure electrode constituent material stored in a supplier 1410 is supplied to an ink station 1440 by a pump 1430. Here, the supplier 1410 may include a controller 1420 for controlling the viscosity and temperature of the ink.

The ink present in the ink station 1440 is coated on one side of a transparent endless belt 1460 by a roller 1450. Here, the transparent endless belt 1460 is rotated by a plurality of guide rollers 1470.

While the transparent endless belt 1460 is rotated by the guide roller 1470, laser 1480 is applied to the transparent endless belt 1460, so that the ink is transferred from the transparent endless belt 1460 to the surface of the second glass layer 283. Through the control of the laser, predetermined ink is transferred to the second glass layer 283 by heat generated by the laser and the pressure of the laser. The transferred ink becomes the pressure electrode 450, 460, or 455. Here, the second glass layer 283 is delivered in a predetermined print direction by a handling system 1490.

Meanwhile, though not shown, the thermal transfer printing method is similar to the laser transfer printing method shown in FIG. 14. The thermal transfer printing method is that a heat radiating device that radiates high temperature heat is added to the transparent endless belt coated with the ink, and the pressure electrode 450, 460, or 455 having a predetermined pattern is formed on the surface of the second glass layer 283.

Through the transfer printing method including the laser transfer printing method and the thermal transfer printing method, there is an advantage in that it is possible to very precisely form the pressure sensor 450 transferred to the second glass layer 283 such that the pressure electrode 450, 460, or 455 has an accuracy of about ±2.5 μm.

The features, structures and effects and the like described in the embodiments are included in one embodiment of the present invention and are not necessarily limited to one embodiment. Furthermore, the features, structures, effects and the like provided in each embodiment can be combined or modified in other embodiments by those skilled in the art to which the embodiments belong. Therefore, contents related to the combination and modification should be construed to be included in the scope of the present invention.

Although embodiments of the present invention were described above, these are just examples and do not limit the present invention. Further, the present invention may be changed and modified in various ways, without departing from the essential features of the present invention, by those skilled in the art. For example, the components described in detail in the embodiments of the present invention may be modified. Further, differences due to the modification and application should be construed as being included in the scope and spirit of the present invention, which is described in the accompanying claims.

What is claimed is:

1. A method for forming a pressure electrode for detecting a touch pressure, on a display module comprising a liquid crystal layer or an organic material layer arranged between an upper glass layer and a lower glass layer, the method comprising:
a pressure electrode forming step of forming the pressure electrode on a bottom surface of the lower glass layer by using Gravure printing method; and
a liquid crystal layer or organic material layer forming step of forming the liquid crystal layer or the organic material layer on a top surface of the lower glass layer.

2. The method of claim 1, wherein the pressure electrode forming step comprises:
forming a pressure electrode pattern by injecting a pressure electrode constituent material into a groove formed in a Gravure roll;
transferring the pressure electrode pattern to a blanket of a rotating transfer roll by rotating the Gravure roll; and
transferring the pressure electrode pattern transferred to the blanket of the transfer roll to the bottom surface of the lower glass layer by rotating the transfer roll.

3. The method of claim 1, wherein the pressure electrode forming step comprises:
forming a pressure electrode pattern in a groove formed in a Cliche plate by injecting a pressure electrode constituent material into the groove;
transferring the pressure electrode pattern to a blanket of a transfer roll by rotating the transfer roll on the Cliché plate; and
transferring the pressure electrode pattern transferred to the blanket of the transfer roll to the bottom surface of the lower glass layer by rotating the transfer roll.

4. The method of claim 1, wherein the pressure electrode forming step comprises:
processing a pressure electrode pattern from a pressure electrode constituent material layer coated on the entire outer surface of a blanket of a transfer roll by rotating the transfer roll on a Cliche plate including a protrusion; and
transferring the pressure electrode pattern processed on the blanket of the transfer roll to the bottom surface of the lower glass layer by rotating the transfer roll.

5. A method for forming a pressure electrode for detecting a touch pressure, on a display module comprising a liquid crystal layer or an organic material layer arranged between an upper glass layer and a lower glass layer, the method comprising:
a pressure electrode forming step of forming the pressure electrode on a bottom surface of the lower glass layer by using an inkjet printing method; and
a liquid crystal layer or organic material layer forming step of forming the liquid crystal layer or the organic material layer on a top surface of the lower glass layer.

6. The method of claim 5, wherein the pressure electrode forming step comprises:
discharging a droplet through a nozzle and attaching to a surface of the lower glass layer; and
drying a solvent of the droplet attached to the lower glass layer.

7. A method for forming a pressure electrode for detecting a touch pressure, on a display module comprising a liquid crystal layer or an organic material layer arranged between an upper glass layer and a lower glass layer, the method comprising:
a pressure electrode forming step of forming the pressure electrode on a bottom surface of the lower glass layer by using a screen printing method; and
a liquid crystal layer or organic material layer forming step of forming the liquid crystal layer or the organic material layer on a top surface of the lower glass layer.

8. The method of claim 7, wherein the pressure electrode forming step comprises:
placing a paste which is a pressure electrode constituent material on a screen pulled with a predetermined tension and moving a squeegee while pressing the squeegee down; and
pushing and transferring the paste to a surface of the lower glass layer through a mesh of the screen.

9. The method of claim 8, wherein the mesh is made of stainless metal.

10. A method for forming a pressure electrode for detecting a touch pressure, on a display module comprising a liquid crystal layer or an organic material layer arranged between an upper glass layer and a lower glass layer, the method comprising:
a pressure electrode forming step of forming the pressure electrode on a bottom surface of the lower glass layer by using a flexographic printing method; and
a liquid crystal layer or organic material layer forming step of forming the liquid crystal layer or the organic material layer on a top surface of the lower glass layer.

11. The method of claim 10, wherein the pressure electrode forming step comprises:
applying ink which is supplied as a pressure electrode constituent material from a supplier on an Anilox roller having a uniform grating;
transferring the ink spread on a surface of the Anilox roller in an embossed pattern to a soft printing substrate mounted on a printing cylinder; and
printing the ink transferred to the soft printing substrate on a surface of the lower glass layer which moves by the rotation of a hard printing roll.

12. A method for forming a pressure electrode for detecting a touch pressure, on a display module comprising a liquid crystal layer or an organic material layer arranged between an upper glass layer and a lower glass layer, the method comprising:
a pressure electrode forming step of forming the pressure electrode on a bottom surface of the lower glass layer by using a transfer printing method; and
a liquid crystal layer or organic material layer forming step of forming the liquid crystal layer or the organic material layer on a top surface of the lower glass layer.

13. The method of claim 12, wherein the pressure electrode forming step comprises:
coating ink which is supplied as a pressure electrode constituent material from a supplier on a transparent endless belt; and
transferring the ink coated on a surface of the transparent endless belt to a surface of the lower glass layer by using laser.

14. The method of claim 12, wherein the pressure electrode forming step comprises:
coating ink which is supplied as a pressure electrode constituent material from a supplier on a transparent endless belt; and
transferring the ink coated on a surface of the transparent endless belt to a surface of the lower glass layer by using a heat radiating device.
